(19) United States
(12) Patent Application Publication
(10) Pub. No.: US 2026/0354240 A1
(43) Pub. Date: Nov. 5, 2026

(54) GLASS-BASED SUBSTRATES AND MICROELECTRONIC ARTICLES WITH INCREASED MECHANICAL RELIABILITY

(71) Applicant: CORNING INCORPORATED, CORNING, NY (US)

(72) Inventors: Konstantin Sergeevich Koreshkov, Espoo (FI); Robert Anthony Schaut, Horseheads, NY (US); Mariia Serova, Espoo (FI); Stanislav Sikulskyi, Corning, NY (US)

(21) Appl. No.: 19/650,607

(22) Filed: Apr. 17, 2026

Related U.S. Application Data
(60) Provisional application No. 63/800,073, filed on May 5, 2025.

(51) Int. Cl. H10W 70/692; H10W 70/60; H10W 70/63; H10W 70/66; H10W 70/685; H10W 70/695

(52) U.S. Cl. CPC H10W 70/692; H10W 70/611; H10W 70/635; H10W 70/66; H10W 70/686; H10W 70/695

(57) ABSTRACT

A microelectronic article that includes a glass-based substrate with a strengthened region that extends from a first surface of the glass-based substrate to a length L within a bulk of the glass-based substrate and a redistribution layer disposed on the first surface of the glass-based substrate, wherein a cut edge surface of the glass-based substrate comprises a maximum edge stress of about 100 MPa in tension or less.

This application claims the benefit of priority to U.S. Provisional Patent Application Ser. No. 63/800,073 filed on May 5, 2025, the content of which is relied upon and incorporated herein by reference in its entirety.

### FIELD

The present specification generally relates to microelectronic articles and, in particular, to methods of making microelectronic articles that minimize the likelihood of lateral fractures in a glass-based substrate of the microelectronic article.

### TECHNICAL BACKGROUND

Glass-based substrates are widely used in microelectronic articles due to attributes such as low dielectric constant, high rigidity, and panel size capability. The glass-based substrates used in microelectronics include an overlay of multiple layers of metal and dielectric materials, referred to as redistribution layers (“RDLs”). The buildup of the RDLs and the differences in coefficient of thermal expansion (“CTE”) between the glass-based substrate and the RDLs may induce stresses that are transferred to the glass-based substrate, resulting in lateral fractures. Conventionally, glass-based substrates with a high CTE may be used to minimize the CTE mismatch between the RDLs and glass-based substrate. However, this limits the glass-based substrates that can be used in these microelectronic articles.

Therefore, a continuing need exists for methods of making microelectronic articles that minimize the likelihood of lateral fractures in a glass-based substrate of the microelectronic article, regardless of the CTE of the glass-based substrate.

### SUMMARY

According to aspects, a microelectronic article is disclosed that comprises a glass-based comprising a strengthened region that extends from a first surface of the glass-based substrate to a length L within a bulk of the glass-based substrate and a redistribution layer disposed on the first surface of the glass-based substrate, wherein a cut edge surface of the glass-based substrate comprises a maximum edge stress of about 100 MPa in tension or less.

According to aspects, a method of making a microelectronic article, the method comprising forming a strengthened region in a glass-based substrate such that the strengthened region extends from a first surface of the glass-based substrate to a length L within a bulk of the glass-based substrate, depositing at least one redistribution layer on the first surface of the glass-based substrate, and singulating the glass-based substrate into a die, wherein a cut edge surface of the glass-based substrate comprises a maximum edge stress of about 100 MPa in tension or less.

According to aspects, a microelectronic article is disclosed that comprises a glass-based substrate comprising a first surface and an opposing second surface, a cut outer edge surface extending between the first surface and the second surface, and a thickness between the first surface and the second surface of about 2.0 mm or less. The microelectronic article further comprising a redistribution layer disposed on the first surface, and wherein the glass-based substrate comprises a silicate glass comprising from about 50.0 mol % to about 90.0 mol % SiO₂, the glass-based substrate has a dielectric constant within a range of 3.8 to 10.0 at a frequency of 10 GHz, the redistribution layer is bonded to the first major surface at an interface therebetween, the redistribution layer comprises a material having a greater coefficient of thermal expansion than that of the glass-based substrate, the glass-based substrate comprises a strengthened region that extends from the first surface to a length L within a bulk of the glass-based substrate, the strengthened region comprises a higher compressive stress than a remainder of the glass-based substrate, and the strengthened region comprises a different alkali metal content than the remainder of the glass-based substrate, and the cut edge outer surface of the glass-based substrate comprises a maximum edge stress of about 100 MPa in tension or less.

It is to be understood that both the foregoing general description and the following detailed description describe various embodiments and are intended to provide an overview or framework for understanding the nature and character of the claimed subject matter. The accompanying drawings are included to provide a further understanding of the various embodiments, and are incorporated into and constitute a part of this specification. The drawings illustrate the various embodiments described herein, and together with the description serve to explain the principles and operations of the claimed subject matter.

### BRIEF DESCRIPTION OF THE DRAWINGS

FIG. 1 is a schematic view of a glass-based panel, according to embodiments described herein;

FIG. 2 is a cross-sectional view of the glass-based panel of FIG. 1, according to embodiments described herein;

FIG. 3 is a schematic view of an exemplary microelectronic article, according to embodiments described herein;

FIG. 4 is a schematic view of a comparison microelectronic article with a lateral fracture formed therein;

FIG. 5 is a cross-sectional view of a glass-based substrate with through-glass vias formed therein, according to embodiments described herein;

FIG. 6 is another schematic view of an exemplary microelectronic article, according to embodiments described herein;

FIG. 7 is a process to produce microelectronic articles, according to embodiments described herein;

FIG. 8A is a perspective view of a glass-based panel with a strip defined therein, according to embodiments described herein;

FIG. 8B is a perspective view of the strip of FIG. 8A, according to embodiments described herein;

FIG. 8C is a portion of the strip of FIG. 8B, according to embodiments described herein; and

FIGS. 9A and 9B shows plots of maximum edge stress of glass-based substrates according to the embodiments described herein along a distance from the midplane of the glass-based substrates.

### DETAILED DESCRIPTION

Reference will now be made in detail to various embodiments of microelectronic articles and methods for making microelectronic articles having a decreased likelihood for glass fractures, regardless of the CTE of a glass-based substrate included in the microelectronic article.

Various embodiments of microelectronic articles and methods of making the same will be described herein with specific reference to the appended drawings.

Ranges may be expressed herein as from “about” one particular value, and/or to “about” another particular value. When such a range is expressed, another embodiment includes from the one particular value and/or to the other particular value. Similarly, when values are expressed as approximations, by use of the antecedent “about,” it will be understood that the particular value forms another embodiment. It will be further understood that the endpoints of each of the ranges are significant both in relation to the other endpoint, and independently of the other endpoint.

Directional terms as used herein—for example up, down, right, left, front, back, top, bottom—are made only with reference to the figures as drawn and are not intended to imply absolute orientation.

Unless otherwise expressly stated, it is in no way intended that any method set forth herein be construed as requiring that its steps be performed in a specific order, nor that with any apparatus specific orientations be required. Accordingly, where a method claim does not actually recite an order to be followed by its steps, or that any apparatus claim does not actually recite an order or orientation to individual components, or it is not otherwise specifically stated in the claims or description that the steps are to be limited to a specific order, or that a specific order or orientation to components of an apparatus is not recited, it is in no way intended that an order or orientation be inferred, in any respect. This holds for any possible non-express basis for interpretation, including: matters of logic with respect to arrangement of steps, operational flow, order of components, or orientation of components; plain meaning derived from grammatical organization or punctuation, and; the number or type of embodiments described in the specification.

As used herein, the singular forms “a,” “an,” and “the” include plural referents unless the context clearly dictates otherwise. Thus, for example, reference to “a” component includes aspects having two or more such components, unless the context clearly indicates otherwise.

“Glass-based substrate,” as described herein, refers to a substrate that comprises amorphous glass or glass-ceramics. The term “glass-ceramic” may refer to solids prepared by controlled crystallization of a precursor glass and have one or more crystalline phases and a residual amorphous glass phase.

“Dispose,” as described herein, refers to any coating, depositing, and/or forming of a material onto a surface using any known method in the art. The disposed material may constitute a layer, as described herein. The phrase “disposed on” may include the instance of forming or depositing a material onto a surface such that the material is in direct contact with the surface and also may include the instance where the material is formed or deposited on a surface, with one or more intervening materials between the disposed material and the surface. The intervening materials may constitute a layer, as described herein.

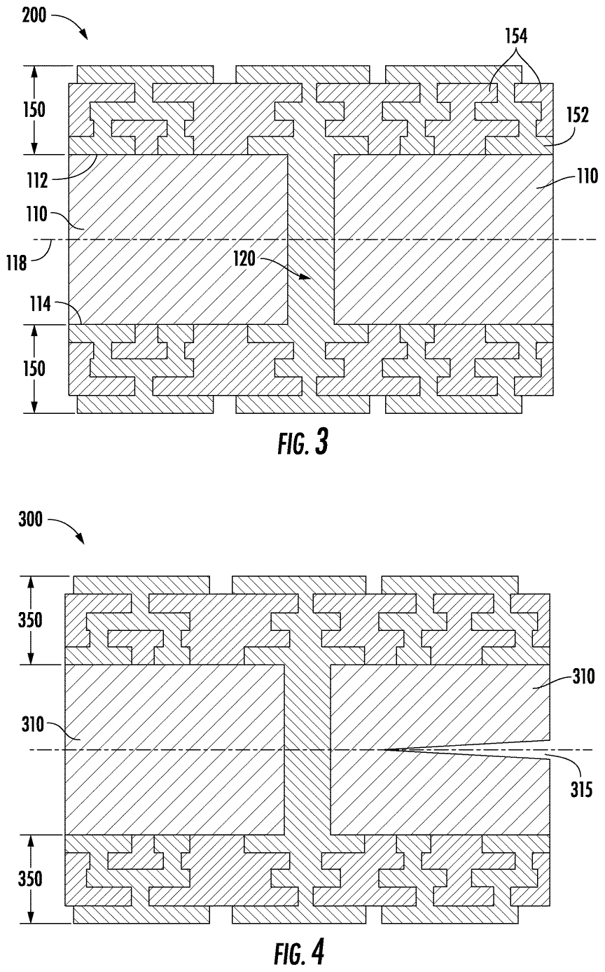

A “layer,” as described herein, refers to a sheet of a material that has generally even thickness covering a surface. A “redistribution layer” (RDL) may refer to the layer comprising dielectric and/or metal materials that make up an integrated circuit of a microelectronic article, as known by those skilled in the art. In some embodiments, a redistribution layer may be “integrated” such that the dielectric material and the metal material present in the redistribution layer are joined in an intertwined manner, such as, for example, in FIG. 3. In such embodiments, the dielectric material may be etched, lasered, or otherwise modified to create gaps that are filled with metal material, and vice versa. This process, described further herein, may result in an “integrated” redistribution layer.

“Coefficient of thermal expansion” (CTE), as described herein, is measured by thermomechanical analysis (TMA), which is a technique used to measure how a material deforms over time or temperature while under a constant force. TMA was performed herein following ASTM E831-24.

As discussed herein, glass-based substrates are widely used in microelectronic articles. Multiple microelectronic articles may be formed by depositing redistribution layers on a glass-based substrate and then singulating the substrates into individual dies. When the individual dies are removed from the remainder of the glass-based substrate, the dies may have weak glass edges. The redistribution layers may impart stresses on the glass and lateral fracturing may occur within the glass that originates from the weakened edges. The fractures may be substantially parallel to the plane of the glass-based substrate. Conventional solutions may include mechanical polishing to strengthen the die edges, but this process may be time consuming and costly to perform on individual dies. Additionally, lateral fracturing may occur during or immediately after removal of the individual dies from the glass-based substrate, so that mechanical polishing would not completely eliminate this problem. Another conventional solution may include chemical strengthening of the glass-based substrate. However, chemical strengthening cannot occur after the formation of metallized through-glass vias and redistribution layers.

Disclosed herein are glass-based substrates and methods of making microelectronic articles that mitigate the aforementioned problems. Specifically, the glass-based substrates disclosed herein comprise a glass-based substrate that has been specifically strengthened to counteract any stresses imparted on the glass-based substrate from the redistribution layers. In some embodiments, the glass-based substrates disclosed herein are specifically ion-exchanged to counteract any stresses imparted on the glass-based substrate from the redistribution layers.

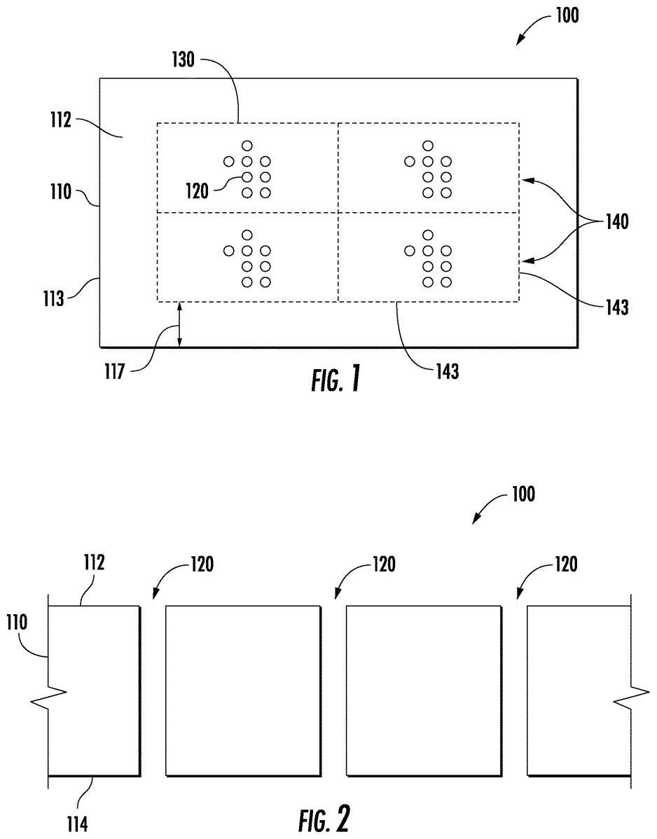

With reference to FIGS. 1 and 2, a glass-based panel 100 is shown according to the embodiments of the present disclosure. FIG. 1 shows a top view of glass-based panel 100, while FIG. 2 shows a cross-sectional view of the panel. Glass-based panel 100 is comprised of a glass-based substrate 110, which comprises a first surface 112 and an opposing second surface 114. Furthermore, glass-based panel 100 comprises an outer edge surface 113, which forms the outer surface that extends from first surface 112 to second surface 114. As also shown in FIGS. 1 and 2, glass-based panel 100 may comprise one or more through-glass vias 120.

As is known in the art, through-glass vias 120 are each an opening within glass-based substate 110 that may form an electrical connect in a microelectronic article. In some embodiments, through glass vias 120 extend from first surface 112 to second surface 114. In other embodiments, through glass vias 120 extend from one of first surface 112 and second surface 114 and through less than an entire thickness of glass-based substrate 110. Furthermore, through-glass vias 120 may each by cylindrical, pinched, or hourglass in cross-section. It is also contemplated that through-glass vias 120 may comprise other cross-sectional configurations.

In embodiments, glass-based panel 100 may comprise 1 or more, or 2 or more, or 4 or more, or 6 or more, or 8 or more, or 10 or more, or 20 or more, or 30 or more, or 40 or more, or 50 or more, or 100 or more, or 200 or more, or 300 or more, or 400 or more, or 500 or more through-glass vias 120. Each through glass-via 120 may comprise a diameter from about 5 microns to about 200 microns, or about 10 microns to about 175 microns, or about 20 microns to about 150 microns, or about 30 microns to about 125 microns, or about 40 microns to about 100 microns, or about 50 microns to about 75 microns, or any range or combination of ranges encompassing these endpoints.

Through-glass vias 120 may have an aspect ratio of about 5:1 or greater, about 10:1 or greater, about 15:1 or greater, about 20:1 or greater, about 25:1 or greater, about 30:1 or greater, about 35:1 or greater, about 40:1 or greater, about 45:1 or greater, or about 50:1. In embodiments, the aspect ratio is in a range from about 5:1 to about 50:1, or about 10:1 to about 45:1, or about 10:1 to about 40:1, or about 15:1 to about 35:1, or about 20:1 to about 30:1, or about 20:1 to about 25:1, or any range or combination of ranges encompassing these endpoints. As used herein, the aspect ratio of through-glass via 120 refers to the ratio of the average thickness of the glass-based substrate 110 (average distance from the first surface 120 to second surface 114) to the minimum diameter of the through-glass via 120.

In the embodiment of FIG. 2, through-glass vias 120 form an opening within glass-based substrate 110 that extends from first surface 112 to second surface 114.

As discussed further below, one or more redistribution layers may be deposited on first surface 112 and/or second surface 114 of glass-based panel 100. After deposition of the redistribution layers, glass based-based panel 100 may be singulated along contour 130 into dies 140. Each individual die 140 may form a microelectronic article. As shown in FIG. 1, each die 140 comprises an outer edge surface 143 which forms the outer surface of the die that extends from first surface 112 to second surface 114. It is also noted that outer edge surface 113 of glass-based panel 100 may be separated by outer edge surface 143 of each die 140 by a portion 117 of glass-based panel 100.

FIG. 3 shows an exemplary microelectronic article 200 with redistribution layers 150 deposited on glass-based substrate 110. It is noted that the singulation of glass-based panel 100 into dies 140 (to form each microelectronic article 200) usually occurs after the deposition of the redistribution layers 150 on glass-based substrate 110. However, it is also contemplated in some embodiments that redistribution layers 150 may be deposited on glass-based substrate 110 after the singulation of the substrate into dies 140. As shown in FIG. 3, each microelectronic article 200 may comprise at least one redistribution layer 150. In some embodiments, microelectronic article 200 may comprise a first redistribution layer 150 on first surface 112 of glass-based substrate 110 and a second redistribution layer 150 on second surface 114 of glass-based substrate 110. In yet other embodiments, microelectronic article 200 may comprise only one redistribution layer 150 on either first surface 112 or second surface 114. In embodiments, redistribution layer 150 is bonded (either directly or indirectly) to first surface 112 and/or second surface 114 such that an interface is formed between redistribution layer 150 and either first surface 112 or second surface 114.

The at least one redistribution layer 150 may comprise, for example, a metal material 152 and a dielectric material 154. In embodiments, metal material 152 and dielectric material 154 are disposed on glass-based substrate 110 in layers. In some embodiments, metal material 152 and dielectric material 154 are deposited on glass-based substrate 110 in alternating layers. In yet some embodiments, such as the embodiment of FIG. 2, metal material 152 and dielectric material 154 are integrated, such that the two materials are deposited on glass-based substrate 110 in an intertwined manner. Metal material 152 and dielectric material 154 may be integrated during the formation process of the at least one redistribution layer 150. It is also contemplated in other embodiments that the at least one redistribution layer 150 comprises dielectric material 154 but not metal material 152. In yet other embodiments, the at least one redistribution layer 150 comprises metal material 152 but not dielectric material 154.

Metal material 152 and dielectric material 154 metal be deposited onto first surface 112 and/or second surface 114 of glass-based substrate 110 using any well-known deposition methods such as, for example, electroplating and/or etching. As shown in FIG. 3, in some embodiments, the redistribution layers 150 may be symmetric with respect to a mid-plane 118 of glass-based substrate 110 such that each redistribution layer 150 on first surface 112 and on second surface 114 comprises the metal material 152 and the dielectric material 154 in the same disposal order and/or same etched pattern reflected across the mid-plane 118. In other embodiments (not shown), the redistribution layers 150 may not be symmetric with respect to the mid-plane 118. It is noted that mid-plane 118 may be parallel (or substantially parallel) to first surface 112 and second surface 114 of glass-based substrate 110.

After the deposition of metal material 152 and dielectric material 152 on glass-based substrate 110, the assembly may be annealed to form microelectronic article 200. In embodiments, during the annealing process, the assembly is heated to a temperature from about 200 °C to about 400 °C, or about 220 °C to about 380 °C, or about 240 °C to about 360 °C, or about 260 °C to about 340 °C, or about 280 °C to about 320 °C, or about 300 °C to about 320 °C, or any range or combination of ranges encompassing these endpoints. After the annealing process, the assembly may be cooled to room temperature. As discussed further below, this annealing process may cause stress in the at least one redistribution layer that then transfers as stress in the glass-based substrate 110.

It is also contemplated, in some embodiments, that the annealing may be performed after the deposition of each layer of metal material 152 and/or dielectric material 154. Therefore, for example, a first layer of metal material 152 may be deposited on glass-based substrate 120 followed by a first annealing. Next, a layer of dielectric material 154 may be deposited on glass-based substrate 110 followed by a second annealing. Then a second layer of metal material 152 may be deposited on glass-based substrate 110 followed by a third annealing. It is noted that the first, second, and third annealing may each comprise different temperature cycles, durations, and/or heating and cooling rates. It is also contemplated that the annealing may be performed after the deposition of the layers of metal material 152, but not after the deposition of the layers of dielectric material 154. After all of the layers of metal material 152 and/or dielectric material 154 are deposited on glass-based assembly 110, the assembly may be annealed again.

Metal material 152 may comprise, for example, copper, aluminium, silver, tin, aluminium-copper, gold, titanium, titanium-tungsten, tantalum, tantalum-nitrogen, chromium, nickel, or combinations thereof. Dielectric material 154 may comprise, for example, polyimide, polybenzoxazoles, polyolefin, polystyrene, epoxy resins, parylene, benzocyclobutene, ring-opened norbornen type polymers, or combinations thereof. In some embodiments, dielectric material 154 comprises a photo-patternable polyimide.

Metal material 152 may also be deposited through an interior of through-glass vias 120, as shown in FIG. 3, in order to provide electrical connections through a thickness of glass-based substrate 110.

In embodiments, the at least one redistribution layer 150 may have a thickness of at least about 500 nanometers (nm). For example, the at least one redistribution layer 150 may have a thickness of at least about 520 nm, at least about 540 nm, at least about 560 nm, at least about 580 nm, at least about 600 nm, at least about 560 nm, at least about 570 nm, at least about 580 nm, at least about 590 nm, at least about 600 nm, at least about 700 nm, at least about 800 nm, at least about 900 nm, at least about 1000 nm, or any range or combination of ranges encompassing these endpoints. Additionally or alternatively, the at least one redistribution layer 150 may have a thickness of about 1000 nm or less, or about 900 nm or less, or about 800 nm or less, or about 700 nm or less, or about 600 nm or less, or about 500 nm or less, or about 400 nm or less, or about 300 nm or less, or about 200 nm or less, or about 100 nm or less, or about 50 nm or less, or about 25 nm or less, any range or combination of ranges encompassing these endpoints.

In embodiments, the at least one redistribution layer 150 may comprise 1 or more layers of each of metal material 152 and dielectric material 154. But it is also contemplated that redistribution layer 150 may only comprise 1 layer of metal material 152 or 1 layer of dielectric material 154. In embodiments, the at least one redistribution layer 150 may comprise 2 or more, or 4 or more, or 6 or more, or 8 or more, or 10 or more, or 12 or more layers of each of metal material 152 and dielectric material 154. In yet some embodiments, the at least one redistribution layer 150 may comprise from 2 to 12, or from 4 to 10, or from 6 to 8 layers of each of metal material 152 and dielectric material 154. In one exemplary example, redistribution layer 150 comprises 6 layers of metal material 152 and 6 layers of dielectric material 154 such that the layers are alternating and intertwined.

Each of the layers of metal material 152 and of dielectric material 154 may comprise a thickness from about 0.50 microns to about 50 microns, or about 0.75 microns to about 45 microns, or about 1 micron to about 40 microns, or about 2 microns to about 35 microns, or about 4 microns to about 30 microns, or about 6 microns to about 25 microns, or about 8 microns to about 20 microns, or about 10 microns to about 15 microns, or any range or combination of ranges encompassing these endpoints.

Without being bound by any particular theory, the application of the one or more redistribution layers 150 may cause stress in the glass-based substrate 110. The stress may be caused by the CTE mismatch between the different materials in the microelectronic article 200, such as the CTE mismatch between metal material 152 and glass-based substrate 110. In embodiments, the at least one redistribution layer 150 comprises a higher CTE than glass-based substrate 110. Furthermore, metal material 154 and dielectric material 152 are annealed and cooled to form the at least one redistribution layer 150, as discussed above. Such annealing and cooling causes the redistribution layer 150 to slightly change shape (e.g., shrink in size). The annealing and cooling of metal material 154 and dielectric material 152 also has an effect on glass-based substrate 110, but due to the mismatch of CTE between redistribution layer 150 and glass-based substrate 110, the substrate reacts differently to the annealing and cooling. For example, in some embodiments, redistribution layer 150 shrinks more than glass-based substrate 110 when annealed and cooled due to the CTE mismatch between these components. This causes a tensile stress in the redistribution layer 150, which then causes a tensile stress in the vertical direction of a singulated outer edge surface of glass-based substrate 110 (once glass-based substrate 110 has been singulated). The tensile stress in the vertical direction of such a singulated outer edge surface is also affected by the build-up process to produce redistribution layer 150 along with the specific material properties and design of microelectronic article 200. For example, with regard to the design, the material of each of the glass-based substrate 110 and the redistribution layer 150, the thickness of glass-based substrate 110, the thickness of redistribution layer 150, and the structure of redistribution layer 150 may each affect how the tensile stress builds in glass-based substrate 110.

The tensile stress in the vertical direction of outer edge surface 143 of glass-based substrate 110 may result in lateral fractures that propagate through glass-based substrate 110 once the substrate is singulated into dies.

FIG. 4 shows a conventional microelectronic article 300 in which redistribution layers 350 are deposited on glass-based substrate 310, causing stress in redistribution layer 350 that causes tensile stress in the vertical direction of the singulated outer edge surface of glass-based substrate 310. The tensile stress in the vertical direction of the singulated outer edge surface manifests as a lateral fracture 315 in glass-based substrate 310. Lateral fracture 315 may split and divide glass-based substrate 310 into two or more portions. This greatly reduces manufacturing yield and increases manufacturing costs to produce the microelectronic articles.

The formation of lateral fractures 315 in the substrate is more likely to occur when a glass-based panel is singulated into the dies to form the microelectronic article. Therefore, in embodiments, the tensile stress that causes the formation of the lateral fractures is induced in the glass-based substrate after the glass-based substrate is singulated into the dies.

An object of the present disclosure is to avoid the formation of lateral fractures 315, thus increasing the mechanical reliability of the produced microelectronic articles. With reference again to FIG. 3, in the embodiments disclosed herein, glass-based substrate 110 is exposed to a process to induce compressive stress in the substrate in order to counteract the stresses induced by the at least one redistribution layer 150. In some embodiments, glass-based substrate 110 is exposed to a chemical process (such as an ion exchange process) or a thermal process (such as a thermal tempering process) or a mechanical process to counteract the stresses induced by the at least one redistribution layer 150.

Glass-based substrate 110 may comprise a silicate glass, an aluminosilicate glass, alkali aluminosilicate glass, alkaline earth aluminosilicate glass, borosilicate glass, boro-aluminosilicate glass, alkali aluminoborosilicate glass, alkaline earth aluminoborosilicate glass, soda-lime glass, or fused quartz (fused silica). Exemplary commercial glass substrates include, but are not limited to, HPFS® ArF Grade Fused Silica sold by Corning Incorporated of Corning, New York under glass codes 7980, 7979, and 8655; Corning carrier glasses sold by Corning Incorporated of Corning, New York under glass codes SG3.4, SG7.8, and SG9.0; and Corning® EAGLE XG® Glass, e.g., boro-aluminosilicate glass also sold by Corning Incorporated of Corning, New York. Other glass substrates include, but are not limited to, Corning Lotus™ NXT Glass, Corning Iris™ Glass, Corning® WILLOW® Glass, Corning® Gorilla® Glass, Corning VALOR® Glass, or PYREX® Glass sold by Corning Incorporated of Corning, New York. Other glass compositions are contemplated.

In embodiments, glass-based substrate 110 may comprise a glass composition comprised of SiO₂ and Al₂O₃. SiO₂ is the primary glass former in the glass compositions disclosed herein and may function to stabilize the network structure of the glass-based substrate 110. The concentration of SiO₂ in the glass compositions disclosed herein should be sufficiently high (e.g., greater than or equal to about 50.0 mol %) to provide basic glass forming capability. The amount of SiO₂ may be limited in some embodiments (e.g., less than about 100.0 mol %) to control the melting point of the glass composition and, thus, may aid in improving the meltability and the formability of the resulting glass-based substrate. In embodiments, the concentration of SiO₂ in the compositions disclosed herein is from about 50.0 mol % to less than about 100.0 mol %, or about 55.0 mol %, to about 95.0 mol %, or about 60.0 mol % to about 90.0 mol %, or about 65.0 mol % to about 85.0 mol5, or about 67.0 mol % to about 80.0 mol %, or about 67.5 mol % to about 75.0 mol %, or about 68.0 mol % to about 75.0 mol %, or about 68.5 mol % to about 75.0 mol %, or about 70.0 mol % to about 75.0 mol %, or about 70.5 mol % to about 75.0 mol %, or about 71.0 mol % to about 75.0 mol %, or about 71.5 mol % to about 75.0 mol %, or about 72.0 mol % to about 75.0 mol %, or about 72.5 mol % to about 75.0 mol %, or about 73.0 mol % to about 75.0 mol %, or about 73.5 mol % to about 75.0 mol %, or about 74.0 mol % to about 75.0 mol %, or about 74.5 mol % to about 75.0 mol %, or about 67.0 mol % to about 72.5 mol %, or about 67.5 mol % to about 72.5 mol %, or about 70.0 mol % to about 72.5 mol %, or any range or combination of ranges formed from these endpoints.

Like SiO₂, Al₂O₃ may also stabilize the glass network of glass-based substrate 110 and additionally provide improved mechanical properties and chemical durability. The amount of Al₂O₃ may also be tailored to the control the viscosity of the glass composition. In embodiments, the concentration of Al₂O₃ in the glass compositions disclosed herein is from about 0.0 mol % to about 25.0 mol %, or about 0.5 mol % to about 22.5 mol %, or about 1.0 mol % to about 20.0 mol %, or about 1.5 mol % to about 17.5 mol %, or about 2.0 mol % to about 15.0 mol %, or about 2.5 mol % to about 12.5 mol %, or about 5.0 mol % to about 10.0 mol %, or about 7.5 mol % to about 10.0 mol % or any range or combination of ranges encompassing these endpoints.

In embodiments, the glass compositions of glass-based substrate 110 further comprises B₂O₃ from about 0.0 mol % to about 20.0 mol %, or about 0.5 mol % to about 17.5 mol %, or about 1.0 mol % to about 15.0 mol %, or about 1.5 mol % to about 12.5 mol %, or about 2.0 mol % to about 10.0 mol %, or about 2.5 mol % to about 7.5 mol %, or about 5.0 mol % to about 7.5 mol %, or any range or combination of ranges encompassing these endpoints.

Furthermore, the glass compositions disclosed herein may comprise one or more alkali metal oxides such as, for example, Na₂O, Li₂O, and K₂O. The alkali metal oxides may be present in the glass compositions from about 0.0 mol % to about 15.0 mol %, or about 0.5 mol % to about 12.5 mol %, or about 1.0 mol % to about 10.0 mol %, or about 1.5 mol % to about 7.5 mol %, or about 2.0 mol % to about 5.0 mol %, or about 2.5 mol % to about 5.0 mol %, or any range or combination of ranges encompassing these endpoints.

The glass compositions disclosed herein may also comprise Cs₂O from about 0.0 mol % to about 10.0 mol %, or about 0.2 mol % to about 0.9 mol %, or about 0.4 mol % to about 0.8 mol %, or about 0.6 mol % to about 0.5 mol %, or any range or combination of ranges encompassing these endpoints.

The glass compositions disclosed herein may also comprise one or more divalent metal oxides such as, for example, MgO, ZnO, BeO, CaO, SrO, BaO, PbO, SnO, and/or HgO. The divalent metal oxides improve the melting behavior of the glass compositions. In embodiments, the glass compositions may comprise the one or more divalent oxides from about 0.0 mol % to about 10.0 mol %, or about 0.2 mol % to about 0.9 mol %, or about 0.4 mol % to about 0.8 mol %, or about 0.6 mol % to about 0.5 mol %, or any range or combination of ranges encompassing these endpoints.

The glass compositions disclosed herein may also comprise one or more fining agents such as, for example, SnO₂. In embodiment the glass compositions comprise SnO₂ from about 0.0 mol % to about 1.0 mol %, or about 0.1 mol % to about 0.9 mol %, or about 0.2 mol % to about 0.8 mol %, or about 0.3 mol % to about 0.7 mol %, or about 0.4 mol % to about 0.6 mol %, or about 0.5 mol % to about 0.6 mol %, or any range or combination of ranges encompassing these endpoints.

In some embodiments, the glass compositions of glass-based substrate 110 may not include any alkaline earth metals. Therefore, in these embodiments, the glass compositions may comprise 0 mol % of each of beryllium (Be), magnesium (Mg), calcium (Ca), strontium (Sr), barium (Ba), and radium (Ra). In other embodiments, the glass compositions of glass-based substrate 110 may comprise low amounts of the alkaline earth metals, such as about 5.0 mol % or less, or about 4.0 mol % or less, or about 3.0 mol % or less, or about 2.0 mol % or less, or about 1.0 mol % or less, or about 0.5 mol % or less or about 0.25 mol % or less, or about 0.1 mol % or less, or about 0.05 mol % or less, or any range or combination of ranges encompassing these endpoints.

In some embodiments, by way of example and not limitation, the composition of glass-based substrate 110 may comprise greater than or equal to 55 mol % and less than or equal to 75 mol % SiO₂, greater than or equal to 5 mol % and less than or equal to 20 mol % Al₂O₃, greater than or equal to 0.5 mol % and less than or equal to 15 mol % B₂O₃, greater than or equal to 0 mol % and less than or equal to 20 mol % Na₂O, greater than or equal to 0 mol % and less than or equal to 1 mol % K₂O, greater than or equal to 0.5 mol % and less than or equal to 5 mol % MgO, greater than or equal to 0 mol % and less than or equal to 15 mol % CaO, greater than or equal to 0 mol % and less than or equal to 2 mol % SrO, greater than or equal to 0 mol % and less than or equal to 1 mol % SnO₂, and greater than or equal to 0 mol % and less than or equal to 1 mol % Fe₂O₃.

In embodiments, glass-based substrate 110 may comprise a coefficient of thermal expansion (CTE) that is greater than or equal to 0.2×10⁻⁶ /°C and less than or equal to 13×10⁻⁶ /°C over a temperature range of −100 °C to 450 °C. In some embodiments, glass-based substrate 110 may have a CTE greater than or equal to 0.2×10⁻⁶ /°C and less than or equal to 1×10⁻⁶ /°C, greater than or equal to 0.2×10⁻⁶ /°C and less than or equal to 12×10⁻⁶ /°C, greater than or equal to 0.2×10⁻⁶ /°C and less than or equal to 10×10⁻⁶ /°C, greater than or equal to 0.2×10⁻⁶ /°C and less than or equal to 8×10⁻⁶ /°C, greater than or equal to 0.2×10⁻⁶ /°C and less than or equal to 6×10⁻⁶ /°C, greater than or equal to 0.2×10⁻⁶ /°C and less than or equal to 4×10⁻⁶ /°C, greater than or equal to 0.2×10⁻⁶ /°C and less than or equal to 2×10⁻⁶ /°C, greater than or equal to 0.5×10⁻⁶ /°C and less than or equal to 13×10⁻⁶ /°C, greater than or equal to 1×10⁻⁶ /°C and less than or equal to 13×10⁻⁶ /°C, greater than or equal to 2×10⁻⁶ /°C and less than or equal to 13×10⁻⁶ /°C, greater than or equal to 4×10⁻⁶ /°C and less than or equal to 13×10⁻⁶ /°C, greater than or equal to 6×10⁻⁶ /°C and less than or equal to 13×10⁻⁶ /°C, greater than or equal to 8×10⁻⁶ /°C and less than or equal to 13×10⁻⁶ /°C, greater than or equal to 10×10⁻⁶ /°C and less than or equal to 13×10⁻⁶ /°C, greater than or equal to 12×10⁻⁶ /°C and less than or equal to 13×10⁻⁶ /°C, or any and all sub-ranges formed from any of these endpoints, over a temperature range of −100 °C to 450 °C.

In embodiments, glass-based substrate 110 has a dielectric constant of about 10.0 or less, or about 9.8 or less, or about 9.6 or less, or about 9.4 or less, or about 9.2 or less, or about 9.0 or less, or about 8.8 or less, or about 8.6 or less, or about 8.4 or less, or about 8.2 or less, or about 8.0 or less, or about 7.8 or less, or about 7.6 or less, or about 7.4 or less, or about 7.2 or less, or about 7.0 or less, or about 6.8 or less, or about 6.6 or less, or about 6.4 or less, or about 6.2 or less, or about 6.0 or less, or about 5.8 or less, or about 5.6 or less, or about 5.4 or less, or about 5.2 or less, or about 5.0 or less, or about 4.8 or less, or about 4.6 or less, or about 4.4 or less, or about 4.2 or less, or about 4.0 or less, or about 3.8 or less. In yet some embodiments, glass-based substrate 110 has a dielectric constant within a range from about 3.8 to about 10.0, or about 4.0 to about 9.8, or about 4.2 to about 9.6, or about 4.4 to about 9.4, or about 4.6 to about 9.2, or about 4.8 to about 9.0, or about 5.0 to about 8.8, or about 5.2 to about 8.6, or about 5.4 to about 8.4, or about 5.6 to about 8.2, or about 5.8 to about 8.0, or about 6.0 to about 7.8, or about 6.2 to about 7.6, or about 6.4 to about 7.4, or about 6.6 to about 7.2, or about 6.8 to about 7.0, or any range or combination of ranges encompassing these endpoints. As described herein, the dielectric constant is measured using a split post dielectric resonator (SPDR), as is known in the art, at a frequency of 10 GHz using a double concave reflecting mirror Fabry-Perot open resonator. The dielectric constant can be measured at different frequencies by adjusting the mirror spacing in the open resonator.

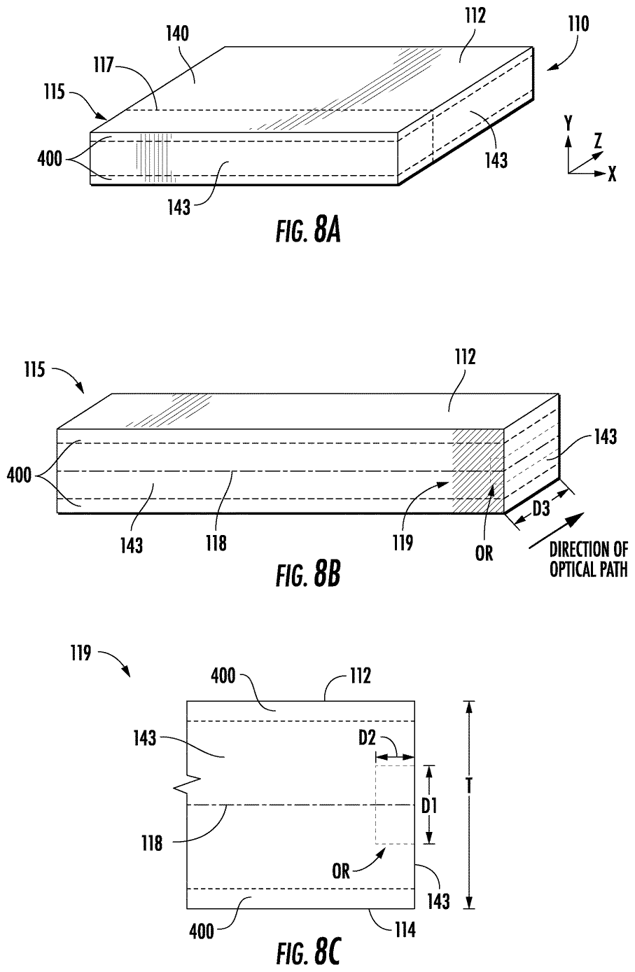

In embodiments, glass-based substrate 110 may have an average thickness from first surface 112 to second surface 114 (as shown in FIG. 8C with reference to thickness T) of about 0.01 mm or greater, about 0.03 mm or greater, about 0.05 mm or greater, about 0.1 mm or greater, about 0.5 mm or greater, about 0.75 mm or greater, about 1.0 mm or greater, or about 1.1 mm or greater, or about 1.25 mm or greater, about 1.5 mm or greater, about 2.0 mm or greater, about 2.5 mm or greater, about 3.0 mm or greater, about 3.5 mm or greater, about 4.0 mm or greater, about 4.5 mm or greater, about 5.0 mm or greater, or any range or combination of ranges encompassing these endpoints. For example, in some embodiments, the substrate thickness is from about 0.1 mm to about 2.0 mm, or about 0.1 mm to about 1.5 mm, or about 0.1 mm to about 1.2 mm, or about 0.1 mm to about 1.1 mm.

As discussed above, glass-based substrate 110 is strengthened by a process that induces compressive stress in the substrate. In embodiments, the process may comprise, for example, a chemical process (such as an ion exchange process) or a thermal process (such as a thermal tempering process) or a mechanical process. The process that induces compressive stress in glass-based substrate 110 may form strengthened regions 400 in glass-based substrate 110, as shown in FIG. 5. In some embodiments, the process to produce strengthened regions 400 in glass-based substrate 110 comprises an ion exchange process. During such an ion exchange process, glass-based substrate 110 is chemically strengthened by which smaller metal ions in the glass are replaced or “exchanged” with larger metal ions of the same valence within a layer of the glass that is close to an outer surface of the glass. The replacement of the smaller metal ions with the larger metal ions creates a compressive stress within the outer surface regions of the glass, thus producing strengthened regions 400.

FIG. 5 shows a cross-sectional view of glass-based substrate 110 with through-glass vias 120 formed therein and wherein glass-based substrate 110 was strengthened to produce strengthened regions 400. As shown in FIG. 5, strengthened regions 400 may be formed along first surface 112 and second surface 114 of glass-based substrate 110 and along interior walls 122 of through-glass vias 120.

The process that induces compressive strength in glass-based substrate 110 (e.g., an ion exchange process), as disclosed herein, may be performed either before or after the formation of through-glass vias 120. In some embodiments, the process that induces compressive strength is performed after the formation of through-glass vias 120.

In embodiments of the ion exchange processes disclosed herein, the smaller metal ions are monovalent alkali metal ions, such as, for example, sodium (Na⁺), potassium (K⁺), or lithium (Li⁺) and these smaller monovalent alkali metal ions in glass-based substrate 110 are exchanged with a larger metal ion of a molten salt, such as, for example, potassium nitrate (KNO₃), potassium sulfate (K₂SO₄), potassium carbonate (K₂CO₃), or potassium chloride (KCl). In yet some other embodiments, smaller monovalent cations, such as, for example, silver (Ag⁺), thallium (Tl⁺), or copper (Cu⁺) in glass-based substrate 110 are exchanged for the alkali metal cations. In some embodiments, glass-based substrate 110 is immersed in a bath of the molten salt to exchange the smaller metal ions for the larger metal ions. Thus, strengthened regions 400 may comprise a different alkali metal content than the remainder of glass-based substrate 110.

During the ion exchange process, glass-based substrate 110 may be immersed in the salt bath for a duration from about 5 minutes to about 40 hours, or about 10 minutes to about 35 hours, or about 20 minutes to about 30 hours, or about 30 minutes to about 25 hours, or about 45 minutes to about 20 hours, or about 1 hour to about 15 hours, or about 2 hours to about 10 hours, or about 5 hours to about 7 hours, or any range encompassing these endpoints. The salt bath may be at a temperature from about 350 °C to about 700 °C, or about 375 °C to about 675 °C, or about 400 °C to about 650 °C, or about 410 °C to about 625 °C, or about 425 °C to about 600430 °C, or about 450 °C to about 575 °C, or about 475 °C to about 550 °C, or about 500 °C to about 525 °C, or any range encompassing these endpoints. As also discussed further below, the duration and temperature of the salt bath determines the length L of strengthened regions 400 within the bulk of glass-based substrate 110, which determines the counteracting force against the redistribution layer 150 induced stress.

In embodiments, the salt bath comprises an alkali metal. Furthermore, in embodiments, the relatively smaller alkali metal ions (e.g., sodium (Na⁺), or potassium (K⁺), lithium (Li⁺)) of glass-based substrate 110 are exchanged with the relatively larger alkali metal ions in the salt bath, thus producing the strengthened regions 400 in glass-based substrate 110. It is noted that the exchange of the relatively smaller alkali metal ions with the relatively larger alkali metal ions generally does not take place throughout the bulk of glass-based substrate 110. Instead, the exchange of the alkali metal ions mainly occurs along and near the outer edge surfaces of glass-based substrate 110 (where the strengthened regions 400 are produced).

In one exemplary embodiment, glass-based substrate 110, with through-glass vias 120 formed therein, is immersed in a KNO₃ salt bath so that Na⁺ ions in the glass are exchanged with K⁺ ions, thus forming strengthened regions 400. In this embodiment, strengthened regions 400 comprise a reduced concentration of Na and a higher concentration of K as compared with the remainder of glass-based substrate 110.

As shown in FIG. 5, strengthened regions 400 extend a length L within the bulk of glass-based substrate 110. For example, strengthened region 400 may extend from first surface 112, second surface 114, and/or interior surface 122 and for length L within the bulk of glass-based substrate 110. The length L of each strengthened region 400 may also be referred to as a depth of compression (“DOC”) of glass-based substrate 110 and refers to the depth within the bulk of glass-based substrate 110 at which the stress within the substrate changes from compressive to tensile. Therefore, at the termination of each strengthened region 400 within the bulk of glass-based substrate 110, the stress within the substrate crosses from a compressive stress to a tensile stress and thus exhibits a stress value of zero, as per ASTM C1422/C1422M-20A, wherein the surface compressive stress is also referred to as case depth in this ASTM standard. It is also noted that length L of strengthened region 400 along first surface 112 may be the same or different from the length L of strengthened region 400 along second surface 114, which may also be the same or different from the length L of strengthened region 400 along surface 122 of through-glass vias 120.

The duration and temperature of the salt bath, as described above, may determine the length L of each strengthened region 400 such that a longer salt bath produces strengthened regions 400 with relatively larger lengths L. In general, longer durations of the salt bath and higher temperatures during the salt bath each result in increased diffusivity of the metal ions into the glass, which then results in strengthened regions 400 with relatively longer lengths L.

Due to the processes disclosed herein that induce compressive stress in glass-based substrate 110 (e.g., the ion exchange processes disclosed herein), strengthened region 400 may have a higher compressive stress than a remainder of glass-based substrate 110. In embodiments, strengthened region 400 may have a surface compressive stress of about 200 MPa or greater, or about 300 MPa or greater, or about 400 MPa or greater, or about 500 MPa or greater, or about 600 MPa or greater, or about 700 MPa or greater, or about 800 MPa or greater, or about 900 MPa or greater, or about 1000 MPa or greater, or any range or combination of ranges formed from these endpoints. In embodiments, the surface compressive stress of strengthened region 400 is in a range from about 200 MPa to about 1000 MPa, or about 300 MPa to about 900 MPa, or about 400 MPa to about 800 MPa, or about 500 MPa to about 700 MPa, or about 600 MPa to about 700 MPa.

Surface compressive stress is measured with a surface stress meter (FSM) such as the FSM-6000, as manufactured by Orihara Industrial Co., Ltd. (Japan). Surface compressive stress measurements rely upon the measurement of the stress optical coefficient (SOC), which is related to the birefringence of the glass article. SOC, in turn, is measured according to Procedure C (Glass Disc Method) described in ASTM standard C770-16, entitled “Standard Test Method for Measurement of Glass Stress-Optical Coefficient,” the contents of which are incorporated herein by reference in their entirety. The values reported for surface compressive stress herein refer to the peak surface compressive stress, unless otherwise indicated. In the embodiments disclosed herein, the surface compressive stress is measured using the FSM for the portions of glass-based substrate 110 that do not comprise through-glass vias 120 and then interpolated, based on these measurements, for the surface compressive stress of the portions of glass-based substrate 110 that do comprise through-glass vias 120.

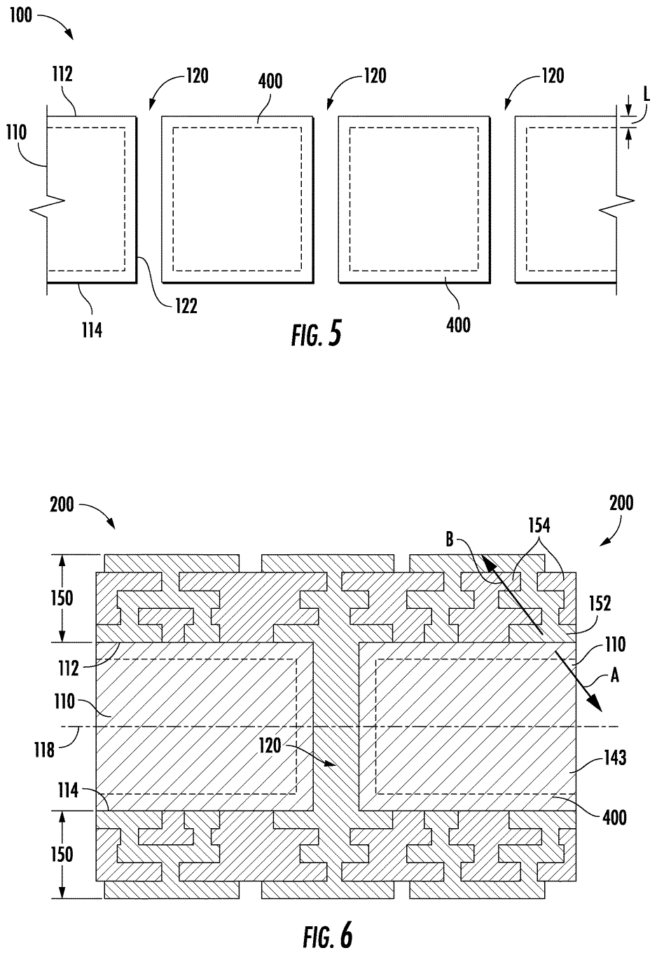

In the embodiments disclosed herein, the processes that induce compressive stress in glass-based substrate 110 (e.g., the ion exchange processes disclosed herein) are optimized to produce strengthened regions 400 that counteract the tensile stress induced by the one or more redistribution layers 150. In FIG. 6, strengthened regions 400 are shown in glass-based substrate 110 of microelectronic article 200, according to the embodiments disclosed herein. As discussed above, strengthened regions 400 impart a compressive stress on glass-based substrate 110. When glass-based panel 100 is singulated into dies 140, the compressive stress manifests as an outward force A on outer edge surfaces 143 of the singulated glass-based substrate 110. Furthermore, the tensile stress from the application of redistribution layers 150 manifests as force B on outer edge surface 143 of glass-based substrate 110. Force A and force B balance and counteract each other.

The magnitude of the force A from the compressive stress may be modified and optimized based upon the length L of strengthened regions 400. In embodiments, the magnitude of the force A is optimized so that it counteracts the magnitude of the force B from the tensile stress. Therefore, for example, the duration and temperature of the salt bath, as described above with reference to the ion exchange processes disclosed herein, are optimized in order to produce a strengthened region 400 with a specific length L that will counteract the tensile stress of force B from redistribution layers 150.

In some embodiments, the net force of force A and force B acting on glass-based substrate 110 is about 0 N.

In the embodiment of FIG. 6, outer edge surface 143 is shown as having a straight and planar profile. However, it is also contemplated in other embodiments, that outer edge surface 143 may comprise or one more bends and/or curves. For example, outer edge surface 143 may comprise one or more portions that have an arcuate profile, a protrusion or indentation, or that comprise wavy or sinusoidal profiles.

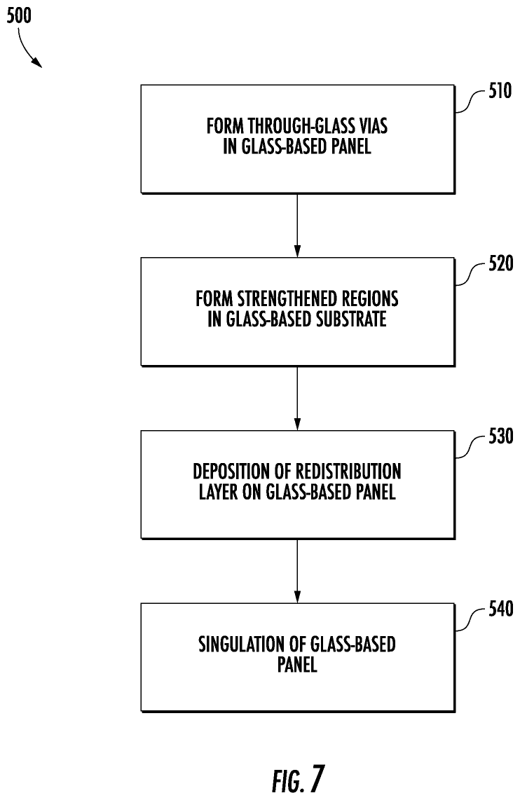

FIG. 7 shows a process 500 to produce microelectronic articles (such as microelectronic article 200) according to embodiments of the present disclosure. In step 510 of process 100, one or more through-glass vias are formed in glass-based panel 100. Formation of through-glass vias 200 in glass-based panel may comprise irradiating glass-based substrate 110 with a laser beam to form a damage track. As described herein, a “damage track” is an area of glass that has been structurally modified with a laser. In embodiments, damage track may comprise a plurality of voids in the glass. In some embodiments, damage track has a lower refractive index and/or a lower density than the surrounding undamaged glass.

Damage tracks, as described herein, may be formed by a variety of laser processes. In embodiments, a pulsed laser beam is focused into a laser beam focal line that is positioned through the bulk of glass-based substrate 110 to form the damage tracks. The laser beam focal line may generate an induced multi-photon absorption within glass-based substrate. The multi-photon absorption produces a material modification within glass-based substrate 110 along the laser beam focal line, thus forming the damage track. Additional description of methods for generating and using a laser beam focal line for forming damage tracks is provided in U.S. Patent Application Publication No. 2021/0269357 and in U.S. Pat. No. 9,517,963, the entirety of each of which are incorporated by reference herein.

Glass-based substrate 110 may then be exposed to one or more etchants to enlarge the damage tracks and to form through-glass vias 120. Without intending to be bound by theory, the damage track may be more susceptible to etching than the undamaged body of glass-based substrate 110. Accordingly, glass may be removed from the damage tracks at a greater rate than from undamaged portions of glass-based substrate 110. This allows through-glass vias 120 to be formed in glass-based substrate 110 from the damage tracks.

At step 520 of process 500, glass-based panel 100 is subject to the process that induces compressive stress in glass-based substrate 110. Therefore, step 520 comprises forming strengthened regions 400 in glass-based substrate 110. In some embodiments, this comprises subjecting glass-based panel 100 to an ion exchange process, as described herein. More specifically, as discussed above, glass-based substrate 110 is immersed in a salt bath to exchange the smaller metal ions within the substrate for larger metal ions during the ion exchange process.

It is noted that step 520 may be performed before or after step 510. Thus, the formation of strengthened regions 400 of step 520 may be conducted before or after through-glass vias 120 are formed in glass-based substrate 110. However, it may be beneficial to conduct formation of strengthened regions 400 of step 520 after the through-glass via 120 formation of step 510 in order to form strengthened regions 400 along interior surfaces 122 of through-glass vias 120.

At step 530 of process 500, the at least one redistribution layer 150 is deposited on glass-based panel 100. As discussed above, deposition of the at least one redistribution layer 150 may comprise depositing metal material 152 and/or dielectric material 154 on glass-based substrate 110 along with annealing of these layers. Furthermore, metal material 152 may be deposited within through-glass vias 120.

At step 540 of process 500, glass-based panel 100 may be singulated and cut into dies 140, thus forming the individual microelectronic articles 200. The singulation of glass-based panel 110 into dies 140 may cause the tensile stress in the vertical direction of outer edge surface 143 of glass-based substate 110, which is caused from the deposition of the at least one redistribution layer 150 on glass-based panel 100. However, in the embodiments disclosed herein, the compressive stress from the ion exchange process, for example, counteracts the stress from the at least one redistribution layer, thus providing a reduced edges stress of the singulated die 140.

In some embodiments of process 500, step 540 may be performed before step 530 or even before step 520. Therefore, in some embodiments, glass-based panel 100 may be singulated into dies 140 after strengthened regions 400 are formed in glass-based substrate 110 but before the deposition of redistribution layer 150 on glass-based substrate 110. Furthermore, in some embodiments, glass-based panel 100 may be singulated into dies 140 before strengthened regions 400 are formed in glass-based substrate 110 and before the deposition of redistribution layer 150 on glass-based substrate 110.

With reference again to FIGS. 1 and 6, glass-based substrate 110 comprises an outer edge surface 143, which is a cut or singulated edge of singulated die 140. Therefore, outer edge surface 143 also forms an outer edge surface of microelectronic article 200. In the embodiments disclosed herein, microelectronic article 200 comprises an outer edge surface 143 with a smaller maximum edge stress compared to outer edge surfaces of comparative microelectronic articles (such as microelectronic article 300). Due to the force A imparted on glass-based substrate 110 that counteracts force B, as discussed above, microelectronic article 200, in the embodiments disclosed herein, comprises such a smaller maximum edge stress.

The maximum edge stress, as used herein, is calculated using the following Equation (1):

$$S = \frac{R}{Cd} \qquad ( 1 )$$

wherein S is the maximum edge stress of the glass-based substrate (MPa), R is the optical retardation of the glass-based substrate (nm), C is the stress-optical coefficient of the glass-based substrate (nm/mm MPa), and dis the optical path distance (nm) of light within the glass-based substrate. In the embodiments disclosed herein, the maximum edge stress S is the vertical component of the edge stress. Thus, the maximum edge stress S is the y-axis component of the edge stress, with reference to the coordinate system in FIG. 8A.

As discussed above, R in Equation (1) is the optical retardation of glass-based substrate 110. In the embodiments disclosed herein, R is measured using ASTM C1422/C1422M-20A, which is incorporated herein by reference. More specifically, in order to measure the optical retardation R, a strip 115 of glass-based substrate 110 is cut from the remainder of glass-based substrate 110, as shown in FIG. 8A. Demarcation line 117 in FIG. 8A shows the boundary of strip 115 from the remainder of glass-based substrate 110.

FIG. 8B shows a perspective view of strip 115 after its separation from the remainder of glass-based substrate 110. Midplane 118 is also shown in FIG. 8B through strip 115. And FIG. 8C shows an enlarged view of portion 119 of strip 115. It is noted that portion 119 is of a portion of strip 115 that encompasses outer edge surface 143.

In accordance with Sections 8.4.1 and 8.4.2 of ASTM C1422/C1422M-20A, the optical retardation R is measured within an area OR that is defined by first distance D1 and second distance D2, as shown in FIG. 8C. First distance D1 is along a thickness direction of glass-based substrate 110 and extends a distance that is 25% of thickness T of glass-based substrate 110, wherein the thickness T extends from first surface 112 to second surface 114 (D1=0.25×T). Furthermore, the first distance D1 is centered about midplane 118. The second distance D2 extends along a plane that is parallel to (or substantially parallel to) first and second surfaces 112, 114 and extends a distance from the outer edge surface 143. The second distance D2 is 20 microns from the absolute outer point of outer edge surface 143. As further shown in FIG. 8B, the area OR extends along a length D3 of strip 115 such that the length D3 is equal to 2 times the thickness T (D3=2×T).

The stress-optical coefficient C in Equation (1) is calculated using the process of ASTM C770-16.

And the optical path distance din Equation (1) is along the length D3, according to ASTM C1422/C1422M-20A.

The maximum outer edge stress S, as calculated using Equation (1), may be in tension or compression. In the embodiments disclosed herein, the maximum edge stress S of outer edge surface 143 is about 100 Megapascals (MPa) in tension or less, or about 95 MPa in tension or less, or about 90 MPa in tension or less, or about 85 MPa in tension or less, or about 80 MPa in tension or less, or about 75 MPa in tension or less, or about 70 MPa in tension or less, or about 65 MPa in tension or less, or about 60 MPa in tension or less or about 55 MPa in tension or less, or about 50 MPa in tension or less, or about 45 MPa in tension or less, or about 40 MPa in tension or less, or about 35 MPa in tension or less, or about 30 MPa in tension or less, or about 25 MPa in tension or less, or about 20 MPa in tension or less, or about 15 MPa in tension or less, or about 10 MPa in tension or less, or about 5 MPa in tension or less, or about 1 MPa in tension or less, or about 0.8 MPa in tension or less, or about 0.5 MPa in tension or less, or about 0.2 MPa in tension or less, or about 0.1 MPa in tension or less, or about 0.08 MPa in tension or less, or about 0.05 MPa in tension or less, or about 0.02 MPa in tension or less, or about 0.01 MPa in tension or less, or about 5000 Pascals (Pa) in tension or less, or about 2500 Pa in tension or less, or a about 2000 Pa in tension or less, or about 1500 Pa in tension or less, or about 1000 Pa in tension or less, or about 500 Pa in tension or less, or about 250 Pa in tension or less, or about 200 Pa in tension or less, or about 100 Pa in tension or less, or about 50 Pa in tension or less, or about 25 Pa in tension or less, or 0 Pa in tension, or any range or combination of ranges encompassing these endpoints.

Furthermore, in the embodiments disclosed herein, the maximum edge stress S of outer edge surface 143 is about 200 MPa in compression or less, or about 300 MPa in compression or less, or about 400 MPa in compression or less, or about 500 MPa in compression or less, or about 600 MPa in compression or less, or about 700 MPa in compression or less, or about 800 MPa in compression or less, or about 900 MPa in compression or less, or about 1000 MPa in compression or less, or any range or combination of ranges encompassing these endpoints.

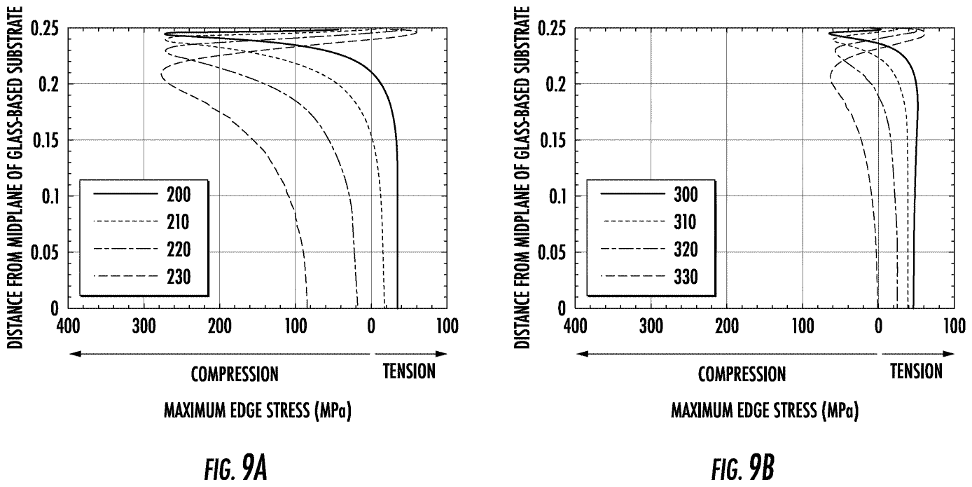

FIGS. 9A and 9B show the modeled maximum edge stress S for singulated ion-exchanged glass-based substrates with a thickness of 0.5 mm. In particular, FIG. 9A shows the modeled edge stress for a singulated glass-based substrate exposed to an ion-exchange treatment with a bath concentration of 100 wt. % potassium nitrate (KNO₃) and FIG. 8B shows the modeled edge stress for a singulated glass-based substrate exposed to an ion-exchange treatment with a bath concentration of 50 wt. % potassium nitrate (KNO₃) and 50 wt. % sodium nitrate (NaNO₃). A redistribution layer 150 formed of a 50 micron thick layer of copper metal material 152 was deposited on each of the glass-based substrates.

Four different plots are plotted in FIG. 9A, each with a different length L of strengthened regions 400 from the ion exchange processes the glass-based substrates were exposed to. In particular, plot 200 corresponds to a glass-based substrate with length L of 5 microns, plot 210 corresponds to a glass-based substrate with a length L of 10 microns, plot 220 corresponds to a glass-based substrate with a length L of 20 microns, and plot 230 corresponds to a glass-based substrate with a length L of 40 microns. Thus, the glass-based substrate of plot 210 was exposed to a longer ion-exchange treatment than the glass-based substrate of plot 200, and the glass-based substrate of plot 220 was exposed to a longer ion-exchange treatment than the glass-based substrate of plot 210, and the glass-based substrate of plot 230 was exposed to a longer ion-exchange treatment than the glass-based substrate of plot 220. The y-axis in FIG. 9A represents the distance from the midplane 118 of the glass-based substrate at the singulated outer edge surface 143 of the glass-based substrates. The x-axis in FIG. 9A represents the maximum edge stress S, as calculated using Equation (1), such that the maximum edge stress S is either in tension or in compression, with 0 MPa showing the border between tension and compression.

Similarly, four different plots are plotted in FIG. 9B, each with a different length L of strengthened regions 400 from the ion exchange processes the glass-based substrates were exposed to. In particular, plot 300 corresponds to a glass-based substrate with length L of 5 microns, plot 310 corresponds to a glass-based substrate with a length L of 10 microns, plot 320 corresponds to a glass-based substrate with a length L of 20 microns, and plot 330 corresponds to a glass-based substrate with a length L of 40 microns. Thus, the glass-based substrate of plot 310 was exposed to a longer ion-exchange treatment than the glass-based substrate of plot 300, and the glass-based substrate of plot 320 was exposed to a longer ion-exchange treatment than the glass-based substrate of plot 310, and the glass-based substrate of plot 330 was exposed to a longer ion-exchange treatment than the glass-based substrate of plot 320. The y-axis in FIG. 9B represents the distance from the midplane 118 of the glass-based substrate at the singulated outer edge surface 143 of the glass-based substrates. The x-axis in FIG. 9B represents the maximum edge stress S, as calculated using Equation (1), such that the maximum edge stress S is either in tension or in compression, with 0 MPa showing the border between tension and compression.

As shown in FIGS. 9A and 9B, the glass-based substrates with the relatively smaller lengths L of strengthened regions 400 comprised maximum edge stress S in tension over a majority of the length of the glass-based substrates. As the length L increased, the maximum edge stress S transitioned more from tension to compression.

Furthermore, the glass-based substrates exposed to the ion-exchange bath with the relatively smaller potassium nitrate concentration (FIG. 9B) comprised relatively higher maximum edge stress S in tension than the glass-based substrates exposed to the ion-exchange bath with the relatively larger potassium nitrate concentration (FIG. 9A).

It is also noted that all of the plots in FIGS. 9A and 9B comprised an edge stress S of less than about 50 MPa in tension.

According to a first aspect, a microelectronic article comprising a glass-based substrate comprising a strengthened region that extends from a first surface of the glass-based substrate to a length L within a bulk of the glass-based substrate, and a redistribution layer disposed on the first surface of the glass-based substrate, wherein a cut edge surface of the glass-based substrate comprises a maximum edge stress of about 100 MPa in tension or less.

According to a second aspect, the microelectronic article of first aspect, wherein the maximum edge stress is about 50 MPa in tension or less.

According to a third aspect, the microelectronic article of second aspect, wherein the maximum edge stress is about 25 MPa in tension or less.

According to a fourth aspect, the microelectronic article of any one of the first through third aspects, wherein the cut edge surface of the glass-based substrate comprises a maximum edge stress of about 1000 MPa in compression or less.

According to a fifth aspect, the microelectronic article of the fourth aspect, wherein the maximum edge stress is about 500 MPa in compression or less.

According to a sixth aspect, the microelectronic article of the fifth aspect, wherein the maximum edge stress is about 200 MPa in compression or less.

According to a seventh aspect, the microelectronic article of any one of the first through sixth aspects, wherein the strengthened region comprises a higher compressive stress than a remainder of the glass-based substrate.

According an eighth aspect, the microelectronic article of any one of the first through seventh aspects, wherein the strengthened region comprises a surface compressive stress of about 200 MPa or greater.

According to a ninth aspect, the microelectronic article of the eighth aspect, wherein the surface compressive stress is about 400 MPa or greater.

According to a tenth aspect, the microelectronic article of any one of the first through ninth aspects, wherein the glass-based substrate further comprises a through-glass via through the glass-based substrate.

According to an eleventh aspect, the microelectronic article of the tenth aspect, wherein the through-glass via comprises an aspect ratio of about 5:1 or greater.

According to a twelfth aspect, the microelectronic article of the eleventh aspect, wherein the aspect ratio is about 10:1 or greater.

According to a thirteenth aspect, the microelectronic article of the twelfth aspect, wherein the aspect ratio is about 15:1 or greater.

According to a fourteenth aspect, the microelectronic article of any one of the first through thirteenth aspects, wherein a thickness of the glass-based substrate is about 2.0 mm or less.

According to a fifteenth aspect, the microelectronic article of any one of the first through fourteenth aspects, wherein the redistribution layer comprises a metal material and a dielectric material.

According to a sixteenth aspect, the microelectronic article of the fifteenth aspect, wherein the metal material comprises copper, aluminum, aluminum-copper, or a combination thereof.

According to a seventeenth aspect, the microelectronic article of the fifteenth or sixteenth aspect, wherein the dielectric material comprises polyimide, polybenzoxazoles, polyolefin, polystyrene, epoxy resins, parylene, benzocyclobutene, ring-opened norbornen type polymers, or combinations thereof.

According to an eighteenth aspect, the microelectronic article of any one of the first through seventeenth aspects, further comprising a second redistribution layer on a second surface of the glass-based substrate.

According to a nineteenth aspect, the microelectronic article of any one of the first through eighteenth aspects, wherein the redistribution layer has a thickness of about 500 nm or greater.

According to a twentieth aspect, the microelectronic article of any one of the first through nineteenth aspects, wherein the glass-based substrate has a coefficient of thermal expansion greater than or equal to 0.2×10⁻⁶ /°C and less than or equal to 13×10⁻⁶ /°C.

According to a twenty-first aspects, a method of making a microelectronic article, the method comprising forming a strengthened region in a glass-based substrate such that the strengthened region extends from a first surface of the glass-based substrate to a length L within a bulk of the glass-based substrate, depositing at least one redistribution layer on the first surface of the glass-based substrate, and singulating the glass-based substrate into a die, wherein a cut edge surface of the glass-based substrate comprises a maximum edge stress of about 100 MPa in tension or less.

According to a twenty-second aspect, the method of the twenty-first aspect, wherein forming the strengthened region in the glass-based substrate comprises immersing the glass-based substrate in a salt bath at a temperature from about 350 °C to about 525 °C to form the strengthened region.

According to a twenty-third aspect, the method of the twenty-first or twenty-second aspect, wherein singulating the glass-based substrate into the die is after the formation of the strengthened region and after the deposition of the at least one redistribution layer on the first surface of the glass-based substrate.

According to a twenty-fourth aspect, the method of any one of the twenty-first through twenty-third aspects, wherein singulating the glass-based substrate into the die is before the formation of the strengthened region in the glass-based substrate.

According to a twenty-fifth aspect, the method of any one of the twenty-first through twenty-fourth aspects, wherein singulating the glass-based substrate into the die is before the deposition of the at least one redistribution layer on the first surface of the glass-based substrate.

According to a twenty-sixth aspect, the method of any one of the twenty-first through twenty-fifth aspects, wherein depositing the redistribution layer comprises depositing a metal material and a dielectric material on the first surface of the glass-based substrate.

According to a twenty-seventh aspect, the method of the twenty-sixth aspect, wherein the metal material comprises copper, aluminum, aluminum-copper, or a combination thereof.

According to a twenty-eighth aspect, the method of the twenty-sixth or twenty-seventh aspects, wherein the dielectric material comprises polyimide, polybenzoxazoles, polyolefin, polystyrene, epoxy resins, parylene, benzocyclobutene, ring-opened norbornen type polymers, or combinations thereof.

According to a twenty-ninth aspect, the method of any one of the twenty-first through twenty-eighth aspects, further comprising forming a through-glass via in the glass-based substrate.

According to a thirtieth aspect, the method of the twenty-ninth aspect, wherein forming the through-glass via in the glass-based substrate is before the formation of the strengthened region in the glass-based substrate.

According to a thirty-first aspect, the method of the twenty-ninth or thirtieth aspect, further comprising depositing a metal material in the through glass via.

According to a thirty-second aspect, the method of any one of the twenty-first through thirty-first aspects, wherein the glass-based substrate has a coefficient of thermal expansion greater than or equal to 0.2×10⁻⁶ /°C and less than or equal to 13×10⁻⁶ /°C.

According to a thirty-third aspect, a microelectronic article comprising a glass-based substrate comprising a first surface and an opposing second surface, a cut outer edge surface extending between the first surface and the second surface, and a thickness between the first surface and the second surface of about 2.0 mm or less. The microelectronic article further comprising a redistribution layer disposed on the first surface, wherein the glass-based substrate comprises a silicate glass comprising from about 50.0 mol % to about 90.0 mol % SiO₂, the glass-based substrate has a dielectric constant within a range of 3.8 to 10.0 at a frequency of 10 GHz, the redistribution layer is bonded to the first major surface at an interface therebetween, the redistribution layer comprises a material having a greater coefficient of thermal expansion than that of the glass-based substrate, the glass-based substrate comprises a strengthened region that extends from the first surface to a length L within a bulk of the glass-based substrate, the strengthened region comprises a higher compressive stress than a remainder of the glass-based substrate, and the strengthened region comprises a different alkali metal content than the remainder of the glass-based substrate, and the cut edge outer surface of the glass-based substrate comprises a maximum edge stress of about 100 MPa in tension or less.

It will be apparent to those skilled in the art that various modifications and variations may be made to the embodiments described herein without departing from the spirit and scope of the claimed subject matter. Thus, it is intended that the specification cover the modifications and variations of the various embodiments described herein provided such modification and variations come within the scope of the appended claims and their equivalents.

What is claimed is:

1. A microelectronic article comprising:
a glass-based substrate comprising a strengthened region that extends from a first surface of the glass-based substrate to a length L within a bulk of the glass-based substrate; and
a redistribution layer disposed on the first surface of the glass-based substrate,
wherein a cut edge surface of the glass-based substrate comprises a maximum edge stress of about 100 MPa in tension or less.

2. The microelectronic article of claim 1, wherein the maximum edge stress is about 50 MPa in tension or less.

3. The microelectronic article of claim 2, wherein the maximum edge stress is about 25 MPa in tension or less.

4. The microelectronic article of any claim 1, wherein the cut edge surface of the glass-based substrate comprises a maximum edge stress of about 1000 MPa in compression or less.

5. The microelectronic article of claim 4, wherein the maximum edge stress is about 500 MPa in compression or less.

6. The microelectronic article of claim 5, wherein the maximum edge stress is about 200 MPa in compression or less.

7. The microelectronic article of claim 1, wherein the strengthened region comprises a higher compressive stress than a remainder of the glass-based substrate.

8. The microelectronic article of claim 1, wherein the strengthened region comprises a surface compressive stress of about 200 MPa or greater.

9. The microelectronic article of claim 8, wherein the surface compressive stress is about 400 MPa or greater.

10. The microelectronic article of claim 1, wherein the glass-based substrate further comprises a through-glass via through the glass-based substrate.

11. The microelectronic article of claim 10, wherein the through-glass via comprises an aspect ratio of about 5:1 or greater.

12. The microelectronic article of claim 11, wherein the aspect ratio is about 10:1 or greater.

13. The microelectronic article of claim 12, wherein the aspect ratio is about 15:1 or greater.

14. The microelectronic article of claim 1, wherein a thickness of the glass-based substrate is about 2.0 mm or less.

15. The microelectronic article of claim 1, wherein the redistribution layer comprises a metal material and a dielectric material.

16. The microelectronic article of claim 15, wherein the metal material comprises copper, aluminum, aluminum-copper, or a combination thereof.

17. The microelectronic article of claim 15, wherein the dielectric material comprises polyimide, polybenzoxazoles, polyolefin, polystyrene, epoxy resins, parylene, benzocyclobutene, ring-opened norbornen type polymers, or combinations thereof.

18. The microelectronic article of claim 1, further comprising a second redistribution layer on a second surface of the glass-based substrate.

19. The microelectronic article of claim 1, wherein the redistribution layer has a thickness of about 500 nm or greater.

20. The microelectronic article of claim 1, wherein the glass-based substrate has a coefficient of thermal expansion greater than or equal to 0.2×10⁻⁶ /°C and less than or equal to 13×10⁻⁶ /°C.

21. A microelectronic article comprising:
a glass-based substrate comprising:
a first surface and an opposing second surface;
a cut outer edge surface extending between the first surface and the second surface; and
a thickness between the first surface and the second surface of about 2.0 mm or less; and
a redistribution layer disposed on the first surface;
wherein:
the glass-based substrate comprises a silicate glass comprising from about 50.0 mol % to about 90.0 mol % SiO₂,
the glass-based substrate has a dielectric constant within a range of 3.8 to 10.0 at a frequency of 10 GHz,
the redistribution layer is bonded to the first major surface at an interface therebetween,
the redistribution layer comprises a material having a greater coefficient of thermal expansion than that of the glass-based substrate,
the glass-based substrate comprises a strengthened region that extends from the first surface to a length L within a bulk of the glass-based substrate, the strengthened region comprises a higher compressive stress than a remainder of the glass-based substrate, and the strengthened region comprises a different alkali metal content than the remainder of the glass-based substrate, and
the cut edge outer surface of the glass-based substrate comprises a maximum edge stress of about 100 MPa in tension or less.
